(19) United States
(12) Patent Application Publication
(10) Pub. No.: US 2009/0104545 A1
(43) Pub. Date: Apr. 23, 2009

(54) Color filter and fabrication method thereof

(75) Inventors: Chao-Chen Chen, Hsinchu (TW); Joseph Lai, Hsinchu (TW); Cheng-Hong Yeh, Taiepei (TW)

Correspondence Address: Joe McKinney Muncy, PO Box 1364, Fairfax, VA, 22038-1364, US

(73) Assignee: VisEra Technologies Company Limited

(21) Appl. No.: 11/976,169

(22) Filed: Oct. 22, 2007

(51) Int. Cl. G03F 1/00

(52) U.S. Cl. 430/7

(57) ABSTRACT

Embodiments disclose a method for fabricating a color filter, comprising: providing a substrate; forming a planarization layer on the substrate; forming a first color layer over the planarization layer; exposing and developing the first color layer to form a patterned first color filter unit over the planarization layer; forming a second color layer over the planarization layer and the patterned first color filter unit; exposing and developing the second color layer to form a patterned second color filter unit over the planarization layer; forming a third color layer over the planarization layer and the patterned first and second color filter units; and etching back or chemical mechanical polishing (CMP) the third color layer to form a patterned third color filter unit over the planarization layer.

### BACKGROUND OF THE INVENTION

1. Field of the Invention

The present invention relates to a method for manufacturing a color filter, and more particularly relates to a method for manufacturing a color filter used for LCDs or color image sensors.

2. Description of the Related Art

Color filters (CF) have been popularly employed in video products/devices, such as color liquid crystal displays (LCDs), charge coupled devices, and image sensors, to obtain ample color information. With regard to LCDs with light, thin, power-saving and full color features, a color filter with three primary colors including red (R), green (G) and blue (B) elements is required for dividing a pixel into R, G and B subpixels. The three primary colors are blended with each other in proportion to create various colors, thus enabling the LCD to display bright, realistic and vivid pictures, enhancing functionality of the LCD.

In a conventional CF process, thin-film color layers including R, G and B layers are successively coated on a glass substrate to serve as R, G and B elements, which must then be precisely aligned to pixel areas on the TFT array substrate. In view of lower manufacturing costs and quality requirements, dyeing, pigment dispersion, printing and electroplating are commonly used to form the R, G and B elements of the color filter. Pigment dispersion, which provides a color filter using a high precision, superior light-resistance and heat-resistance process, has become a major process used for TFT-type color filters.

The pigment dispersion method applied in the conventional color filter process includes the following steps. A black photosensitive resin material is spin-coated on a glass substrate, and then subjected to a photolithography process, that is, exposed to light, developed and baked, to form a black matrix (BM) having an array of openings for color elements. Then, red, green, and blue resin materials are respectively spin-coated and subjected to the photolithography process to form three different color elements, such that the red, green, and blue elements fill the opening of the black matrix in a desired arrangement. Since the pigment dispersion method includes resin coating, exposure, and development procedures, any inaccuracy in the processes would cause the color elements to have inaccurate alignments. For example, color cross-talk between two adjacent color elements may occur. Should color cross-talk occur during the fabrication process, it will be necessary to rework the defective product. Reworking defective products result in lower productivity, increased processes cycle time, and a production bottleneck due to the loading of the photolithography process for rework.

Therefore, it is necessary to solve the above issues by a new method for fabricating a color filter.

### BRIEF SUMMARY OF THE INVENTION

A detailed description is given in the following embodiments with reference to the accompanying drawings.

An embodiment of the invention provides a method for fabricating a color image sensor device, comprising: providing a substrate comprising a sensor pixel array; forming an intermetal dielectric layer on the substrate, covering the sensor pixel array; blanketly forming a first planarization layer on the intermetal dielectric layer; forming a first color layer over the first planarization layer; exposing and developing the first color layer to form a patterned first color filter unit over the sensor pixel array; forming a second color layer over the first planarization layer and the patterned first color filter unit; exposing and developing the second color layer to form a patterned second color filter unit next to the patterned first color filter unit over the sensor pixel array; forming a third color layer over the first planarization layer and the patterned first and second color filter units; and etching back or performing chemical mechanical polishing (CMP) to form a patterned third color filter unit between the patterned first and second color filter units over the sensor pixel array.

Another embodiment of the invention discloses a method for fabricating a color filter, comprising: providing a substrate having a display area; forming a light shielding layer on the substrate, and separating the display area into a plurality of sub-pixels; forming a first color layer over the substrate and in the plurality of sub-pixels; exposing and developing the first color layer to form a patterned first color filter unit in the plurality of sub-pixels; forming a second color layer over the substrate and the patterned first color filter unit and in the plurality of sub-pixels; exposing and developing the second color layer to form a patterned second color filter unit in the plurality of sub-pixels; forming a third color layer over the substrate and the patterned first and second color filter units and in the plurality of sub-pixels; etching back or chemical mechanical polishing (CMP) the third color layer to form a patterned third color filter unit in the plurality of sub-pixels; and forming a conductive layer over the light shielding layer.

A further embodiment of the invention discloses a method for fabricating a color filter, comprising: providing a substrate; forming a planarization layer on the substrate; forming a first color layer over the planarization layer; exposing and developing the first color layer to form a patterned first color filter unit over the planarization layer; forming a second color layer over the planarization layer and the patterned first color filter unit; exposing and developing the second color layer to form a patterned second color filter unit over the planarization layer; forming a third color layer over the planarization layer and the patterned first and second color filter units; and etching back or chemical mechanical polishing (CMP) the third color layer to form a patterned third color filter unit over the planarization layer.

### BRIEF DESCRIPTION OF THE DRAWINGS

The present invention can be more fully understood by reading the subsequent detailed description and examples with references made to the accompanying drawings, wherein:

FIG. 1A to FIG. 1H are cross sections of a method for forming a color filter according to an embodiment, illustrating fabrication steps thereof.

FIG. 2A to FIG. 2H are cross sections of a method for forming a color filter according to a preferred embodiment, illustrating fabrication steps thereof.

FIG. 2I shows a color filter array including a pattern of red (R), green (G) and blue (B) filters according to an embodiment.

FIG. 3A to FIG. 3K are cross sections of a method for forming a color image sensor according to an embodiment, illustrating fabrication steps thereof.

FIG. 4 is a cross-section view of an LCD according to an embodiment.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention will be described in greater detail by referring to the accompanying drawings. In the accompanying drawings, like and/or corresponding elements are referred to by like reference numerals. The following description discloses the best-contemplated mode of carrying out the invention. This description is made for the purpose of illustrating the general principles of the invention and should not be taken in a limiting sense. The scope of the invention is best determined by reference to the appended claims.

In this specification, expressions such as “overlying the substrate”, “above the layer”, or “on the film” simply denote a relative positional relationship with respect to the surface of a base layer, regardless of the existence of intermediate layers. Accordingly, these expressions may indicate not only the direct contact of layers, but also, a non-contact state of one or more laminated layers.

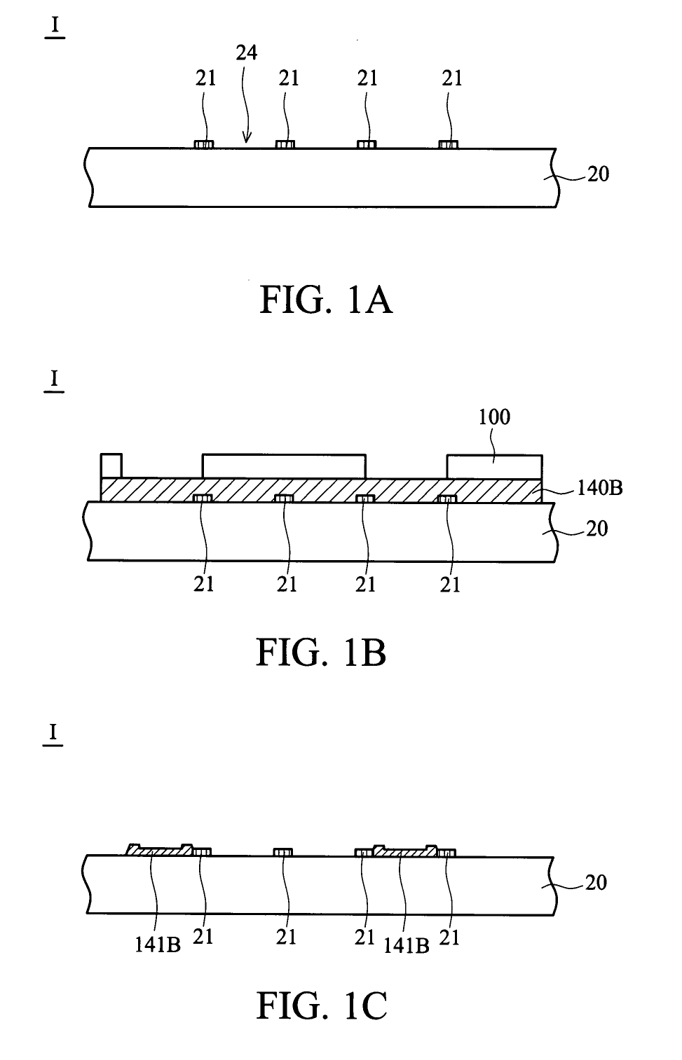

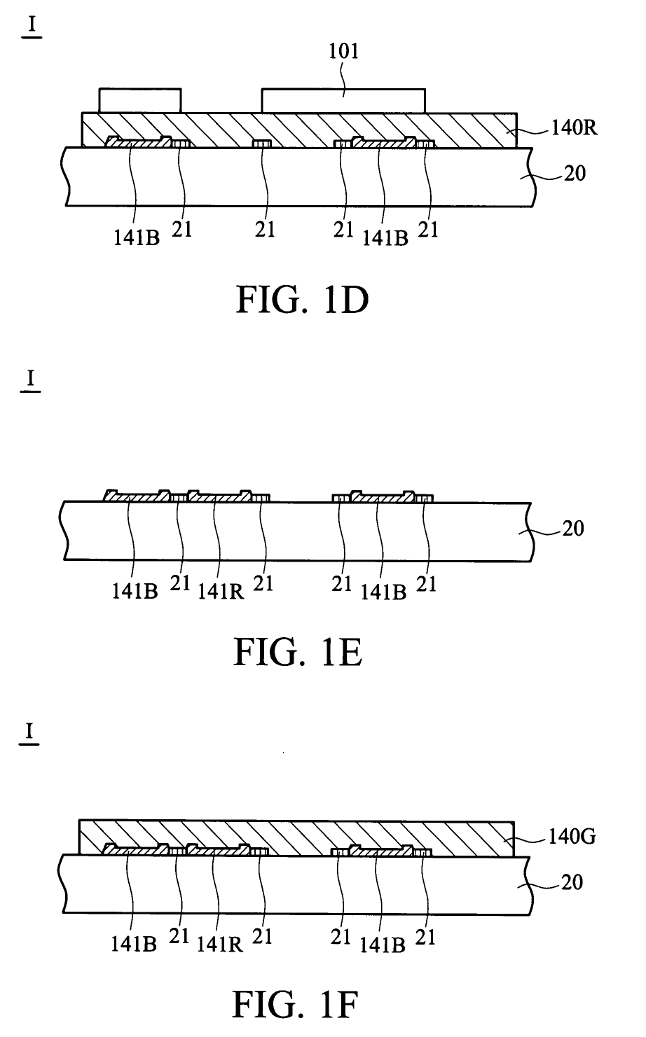

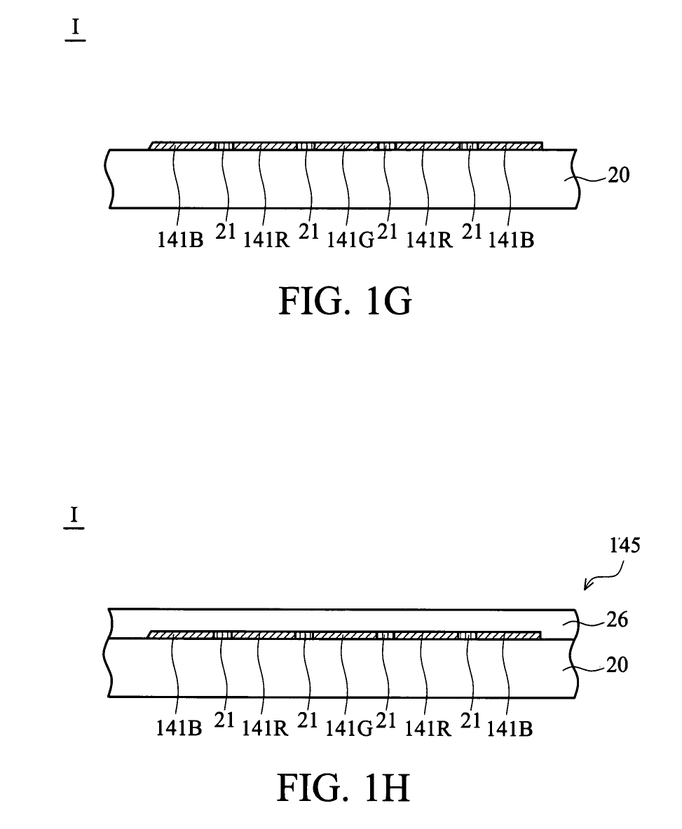

As shown in FIGS. 1A-1H, the cross sections show fabrication steps of a color filter according to an embodiment.

As shown in FIG. 1A, a substrate 20, such as a plastic or glass substrate, is provided with a display region I, wherein a light shielding layer 21 is formed on the substrate 20 separating the display region I into a plurality of sub-pixels 24. The material of the light shielding layer 21 can be black resin or black acrylic. The light shielding layer 21 may be formed by photolithography.

As shown in FIGS. 1B and 1C, a blue color layer 140B is formed over the substrate 20. Next, a patterned photoresist layer 100 is formed on the blue color layer 140B and then sequentially exposed and developed, thus forming the patterned blue color filter units 141B over the substrate 20. After that, as shown in FIGS. 1D and 1E, a red color layer 140R is formed over the substrate 20 and the patterned blue color filter units 141B. Next, a patterned photoresist layer 101 is formed on the red color layer 140R and then sequentially exposed and developed, thus forming the patterned red color filter units 141R next to the patterned blue color filter units 141B over the substrate 20. After that, as shown in FIGS. 1F and 1G, a green color layer 140G is formed over the substrate 20, the patterned red color filter units 141R and the patterned blue color filter units 141B. Next, etching back or chemical mechanical polishing (CMP) is performed thereon, forming the patterned green color filter units 141G between the patterned blue color filter units 141B and the patterned red color filter units 141R over the substrate 20.

As shown in FIG. 1H, a conductive layer 26 is formed overlying the substrate 20 to cover the patterned blue color filter units 141B, the patterned red color filter units 141R, the patterned green color filter units 141G and the light shielding layer 21 by sputtering or the like. The material of the conductive layer 26 can be ITO, ZnO or other metal doped in ZnO such as ZnO:Sn, ZnO:V, ZnO:Co, ZnO:Al, ZnO:Ga, ZnO:Ti or ZnO:In. Following the above steps, a color filter 145 is formed.

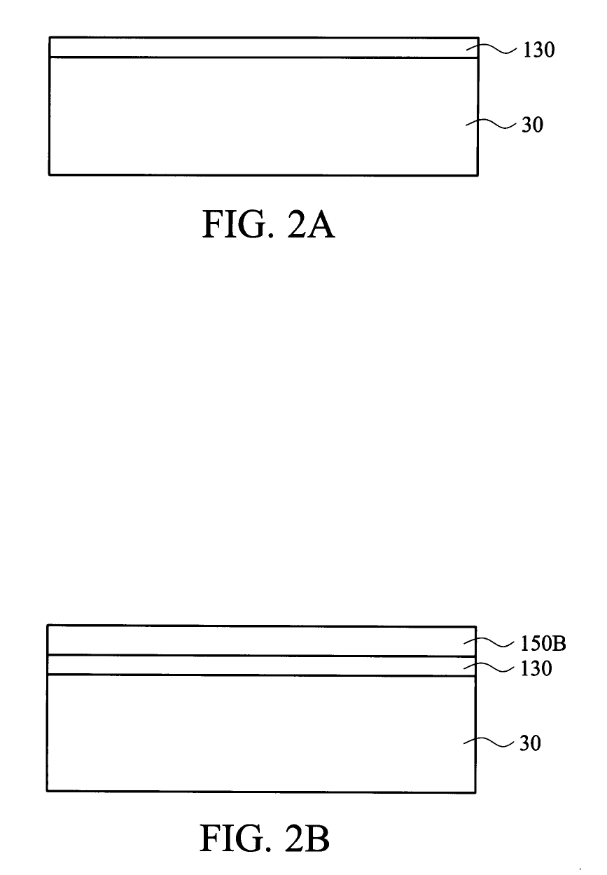

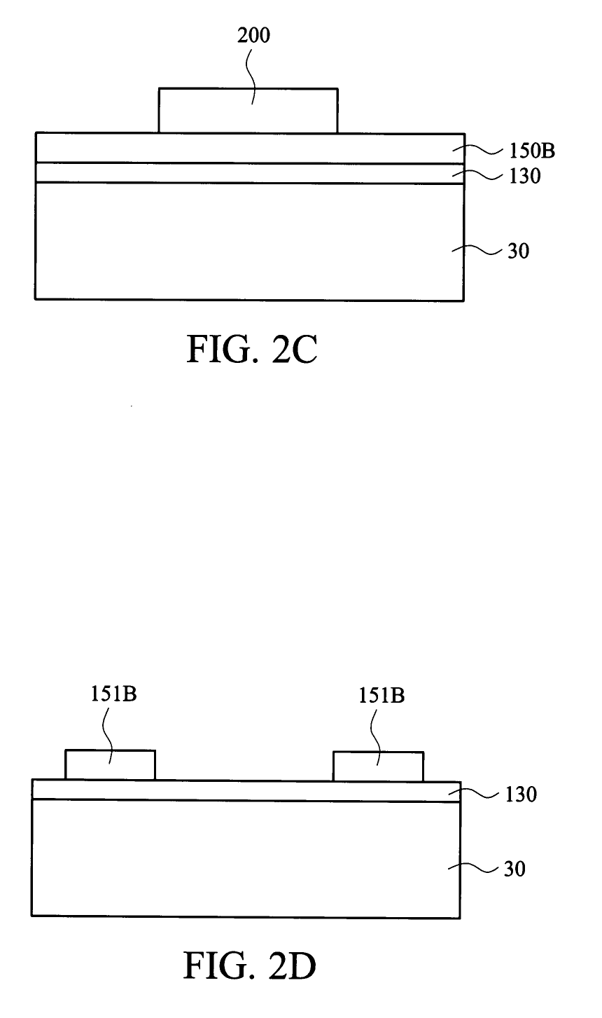

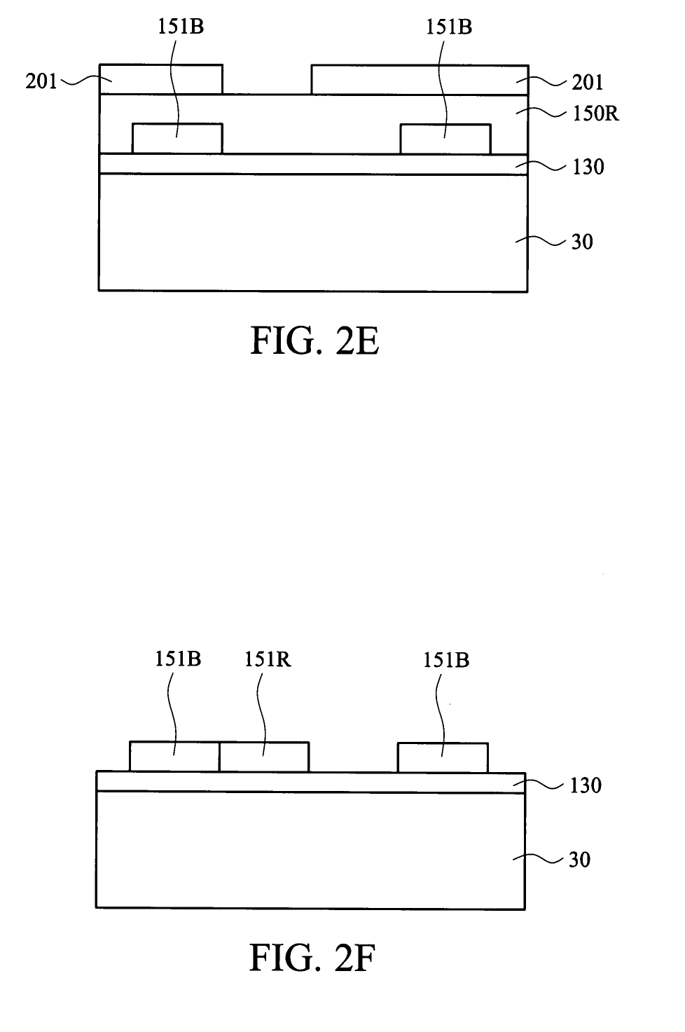

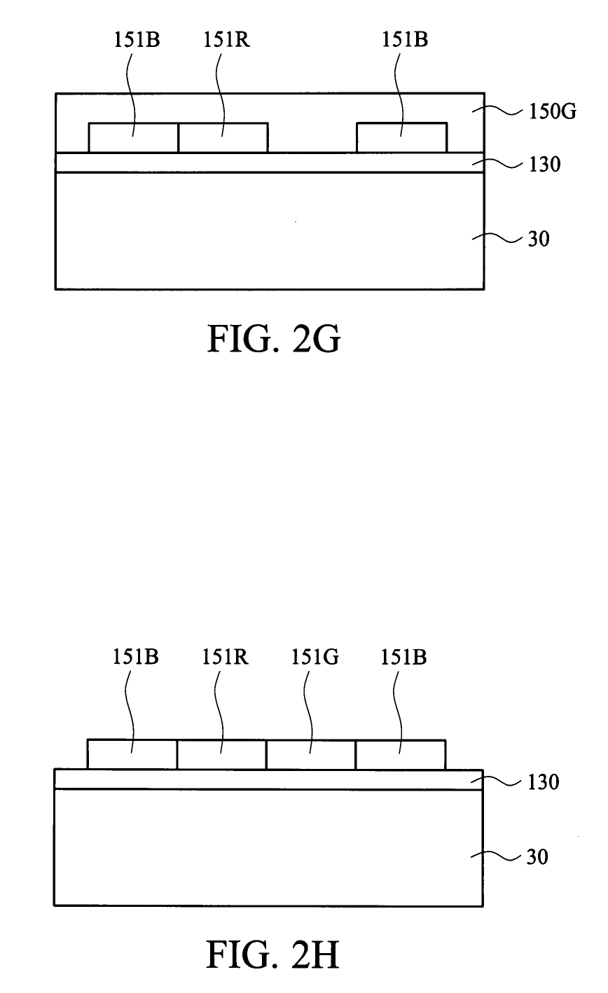

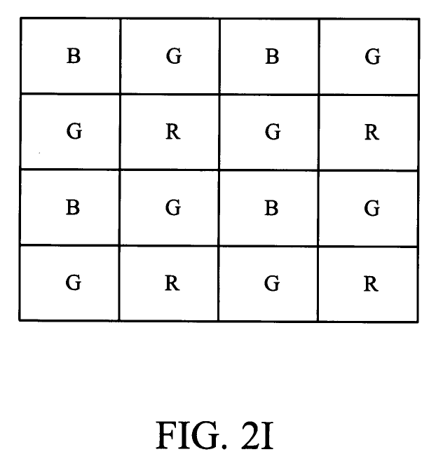

Referring to FIGS. 2A-2I, a preferred embodiment of fabricating a color filter is shown.

As shown in FIG. 2A, a substrate 30 is provided and a planarization layer 130 is formed thereon. The planarization layer 130 may comprise photoresists with light transmittance not less than 95%, such as a transparent resin or other negative-type photoresists. The planarization layer 130 has high tolerance to exposure and corrosion from developers used and has a plane surface after planarization is performed thereon.

As shown in FIGS. 2B and 2D, a blue color layer 150B is formed over the planarization layer 130. Next, a patterned photoresist layer 200 is formed on the blue color layer 150B and then sequentially exposed and developed, thus forming the patterned blue color filter units 151B over the planarization layer 130. After that, as shown in FIGS. 2E and 2F, a red color layer 150R is formed over the planarization layer 130 and the patterned blue color filter units 151B. Next, a patterned photoresist layer 201 is formed on the red color layer 150R and then sequentially exposed and developed, forming the patterned red color filter units 151R next to the patterned blue color filter units 151B over the planarization layer 130. After that, as shown in FIGS. 2G and 2H, a green color layer 150G is formed over the planarization layer 130, the patterned blue color filter units 151B and the patterned red color filter units 151R. Next, etching back or chemical mechanical polishing (CMP) is performed thereon, forming the patterned green color filter units 151G between the patterned blue color filter units 151B and the patterned red color filter units 151R over the planarization layer 130. Therefore, forming a color filter 160. FIG. 2I shows a color filter array including a pattern of red (R), green (G) and blue (B) filters according to this embodiment.

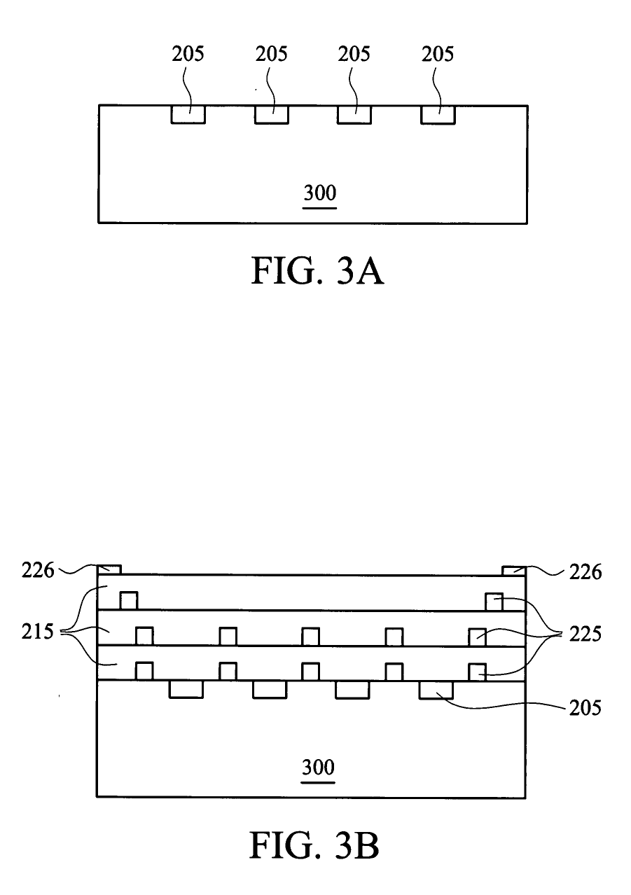

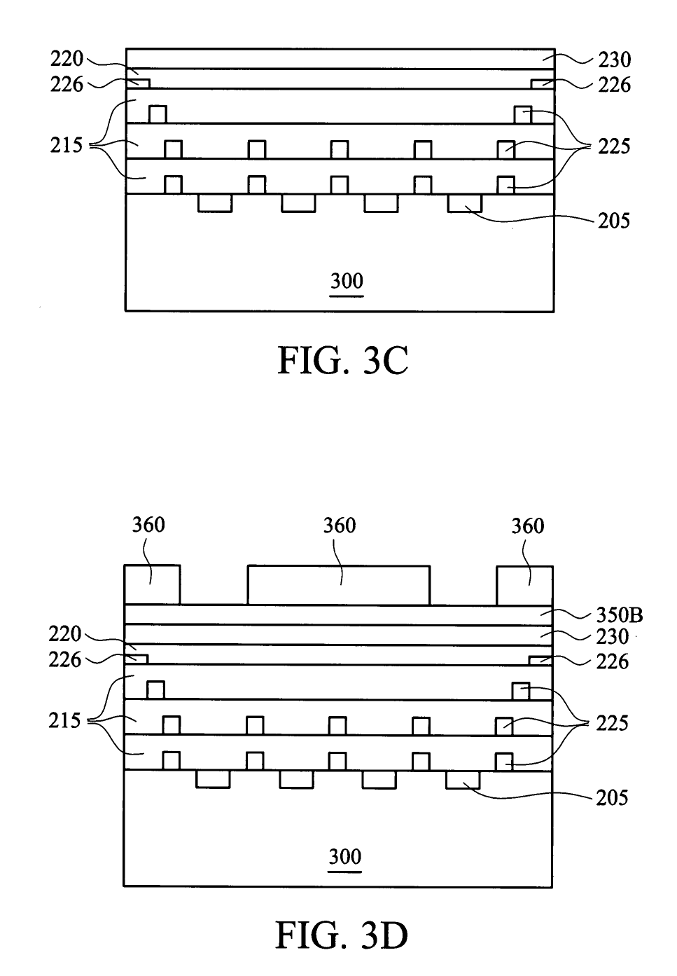

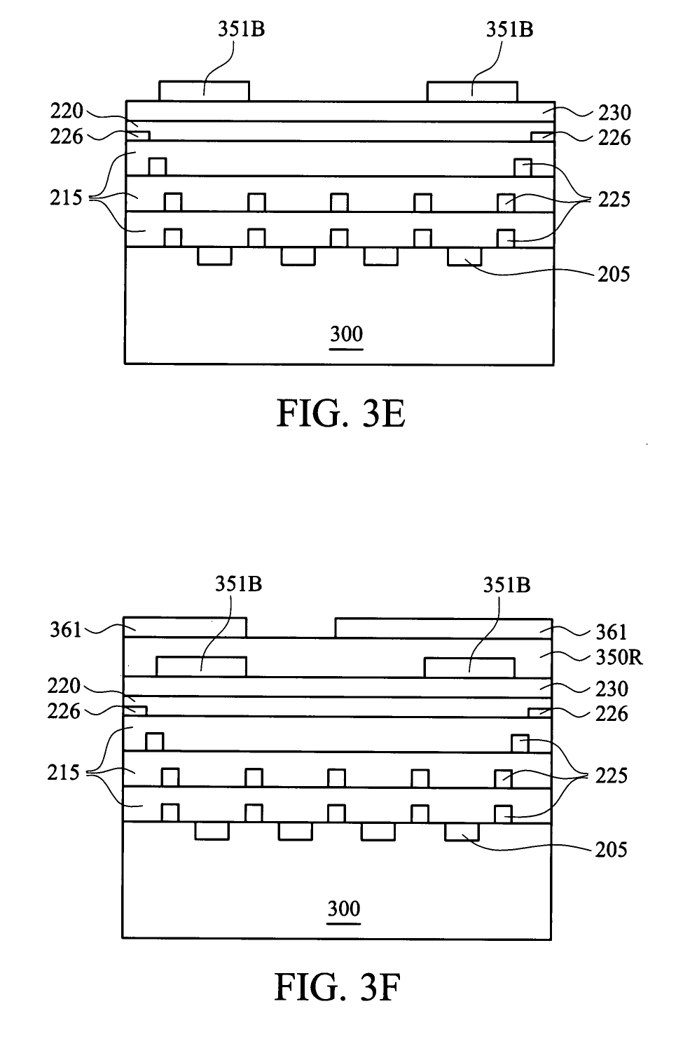

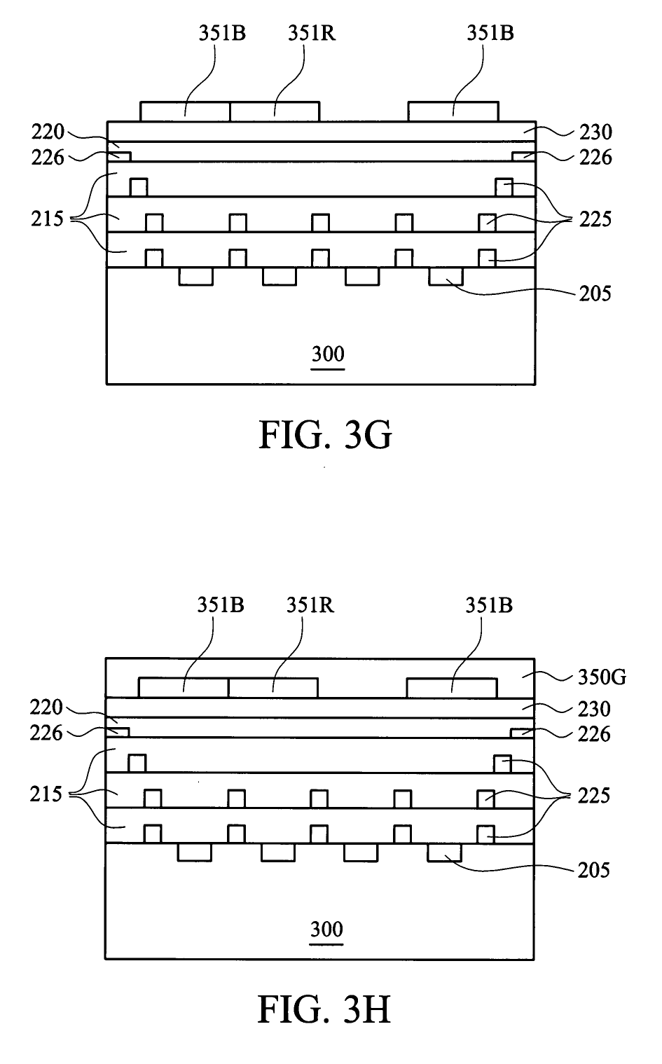

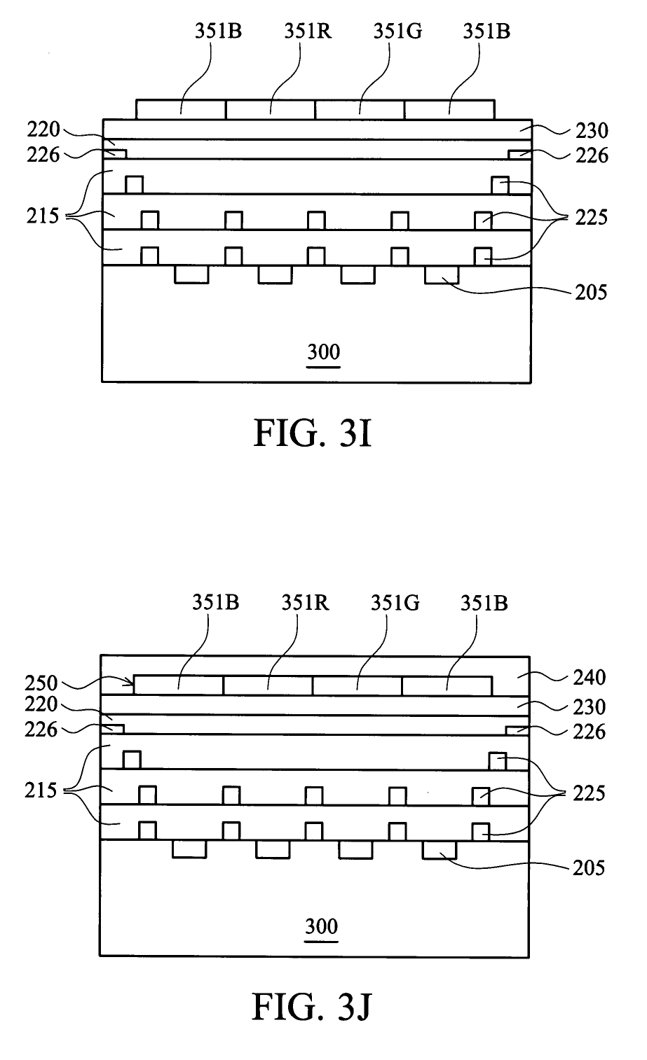

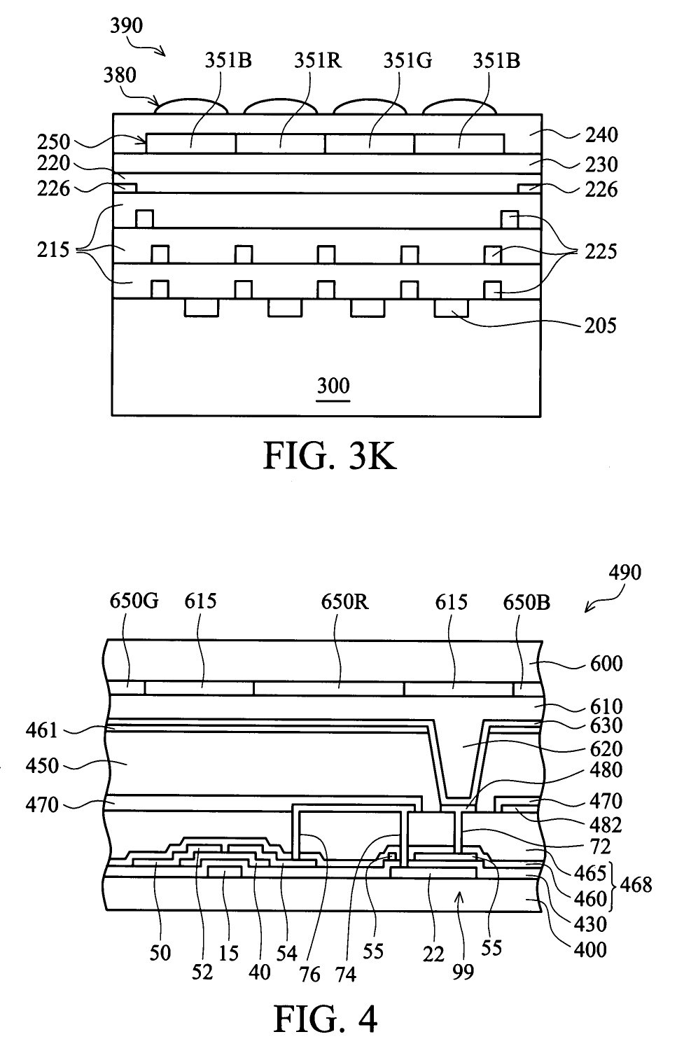

Referring to FIGS. 3A-3J, a preferred embodiment of fabricating a color image sensor is shown.

As shown in FIG. 3A, a substrate 300 is provided comprising a sensor pixel array 205. In one embodiment, the sensor pixel array 205 includes a P-N junction device (e.g., a diode). Next, as shown in FIG. 3B, two or more intermetal dielectric (IMD) layers 215 are formed on the substrate 300 covering the sensor pixel array 205, with each of the IMD layers 215 including a metal layer 225. Moreover, a bonding pad 226 may be formed on the upper most IMD 215. In this embodiment, the IMD layers 215 may be formed by atomic layer deposition (ALD), chemical vapor deposition (CVD) such as plasma enhanced CVD (PECVD), high density plasma CVD (HDP-CVD), low pressure CVD (LPCVD), evaporation, or any other suitable technique.

As shown in FIG. 3C, a passivation layer 220 and a first planarization layer 230 is successively formed over the IMD layers 215. The first planarization layer 230 may comprise photoresists with light transmittance not less than 95%, such as a transparent resin or other negative-type photoresists. The first planarization layer 230 has high tolerance to exposure and corrosion from developers used and has a plane surface after planarization is performed thereon.

As shown in FIG. 3D, a blue color layer 350B is formed over the first planarization layer 230. Next, a patterned photoresist layer 360 is formed on the blue color layer 350B and then sequentially exposed and developed, thus the forming patterned blue color filter units 351B over the sensor pixel array 205 as shown in FIG. 3E.

As shown in FIGS. 3F and 3G, a red color layer 350R is formed over first planarization layer 230 and the patterned blue color filter units 351B. Next, a patterned photoresist layer 361 is formed on the red color layer 350R and then sequentially exposed and developed, forming the patterned red color filter units 351R next to the patterned blue color filter units 351B over the sensor pixel array 205.

As shown in FIGS. 3H and 31, a green color layer 350G is formed over the first planarization layer 230, the patterned blue color filter units 351B and the patterned red color filter units 351R. Next, etching back or chemical mechanical polishing (CMP) is performed thereon, forming the patterned green color filter units 351G between the patterned blue color filter units 351B and the patterned red color filter units 351R over the sensor pixel array 205. Therefore, forming a color filter array 250.

Referring to FIG. 3J, a second planarization layer 240 is formed over the first planarization layer 230 to cover the color filter layers 351R, 351G, 351B. The second planarization layer 240 may comprise photoresists with light transmittance not less than 95%, such as a photosensitive polyimide or other negative-type photoresists. The second planarization layer 240 may comprise the same material as that of the first planarization layer 230.

Referring to FIG. 3K, a microlenses array 380 is then formed on the second planarization layer 240 corresponding to the sensor pixel array 205 and the color filter array 250. Following the above steps, a color image sensor 390 is formed.

It is noted that the color filter array 250 having a high degree of flatness can be formed if the patterned green color filter units 351G is formed by CMP, and thus the second planarization layer 240 may be omitted.

FIG. 4 is a cross-section view of an LCD according to an alternative embodiment. In FIG. 4, a gate 15 and a first metal layer 22 is formed on a lower substrate 400. A dielectric layer 430 covers the gate 15, the first metal layer 22 and the lower substrate 400. A semiconductor layer 40, serving as a channel layer, is then formed on the dielectric layer 430 above the gate 15.

A source 52 is then formed to extend onto part of the semiconductor layer 40. A drain 54 is simultaneously formed on part of the semiconductor layer 40 and the dielectric layer 430 and a second metal layer 55 is formed on part of the dielectric layer 430. The first metal layer 22, the second metal layer 55 and the dielectric layer 430, interposed therebetween, substantially constitute a storage capacitor structure 99.

Next, a passivation layer 460 is blanketly formed overlying the lower substrate 400. In order to obtain a smooth surface, an organic planarization layer 465 is optionally formed on the passivation layer 460. It is noted that the organic planarization layer 465 may be omitted. In order to simplify the illustration, the passivation layer 460 and the organic planarization layer 465 are generally referred to as an insulating layer 468.

A first opening 72, a second opening 74 and a third opening 76 are formed. The first opening 72 penetrates the insulating layer 468 to expose the second metal layer 55. The second opening 74 penetrates the insulating layer 468 and the dielectric layer 430 to expose the first metal layer 22. The third opening 76 penetrates the insulating layer 468 to expose the drain 54.

A first transparent conductive layer 480 is then formed on a portion of the insulating layer 468 and in the first opening 72 to electrically connect the second metal layer 55. A second transparent conductive layer 482, serving as a pixel electrode 482, is formed on a portion of the insulating layer 468 and in the second opening 74 and the third opening 76 to electrically connect the first metal layer 22 and the drain 54. An alignment layer 470 is then formed on the second transparent conductive layer 482.

Referring to FIG. 4 again, an upper substrate 600, such as glass, opposite the lower substrate 400 is provided. A color filter 610 is formed on the interior of the upper substrate 600. There are several steps in the formation process of the color filter 610 (not shown). For example, a light shielding layer 615 is formed on the upper substrate 600 for defining a plurality of sub-pixels. Then, a blue color layer is formed over the substrate, a patterned photoresist layer is formed on the blue color layer, and sequential exposing and developing is performed. Thus, forming the patterned blue color filter units 650B over the upper substrate 600. A red color layer is formed over the upper substrate 600 and the patterned blue color filter units 650B. Next, a patterned photoresist layer is formed on the red color layer and then exposed and developed to form the patterned red color filter units 650R next to the patterned blue color filter units 650B over the substrate 600. A green color layer is formed over the upper substrate 600, the patterned red color filter units 650R and the patterned blue color filter units 650B. Next, etching back or chemical mechanical polishing (CMP) is performed thereon, forming the patterned green color filter units 650G between the patterned red color filter units 650R and the patterned blue color filter units 650B over the substrate 600.

An insulating spacer 620 is then formed on a portion of the color filter 610 (i.e. the upper substrate 600) and extended into a liquid crystal layer 450 interposed between the lower substrate 400 and the upper substrate 600. The insulating spacer 620 maintains a cell gap of the liquid crystal layer 450. A portion of the light shielding layer corresponds to the insulating spacer 620.

A conformal third transparent conductive layer 630 serving as a common electrode 630 is formed on the interior of the color filter 610 and the surface of the insulating spacer 620 to electrically connect the first conductive layer 480. An alignment layer 441 is then formed on the third transparent conductive layer 630. Finally, a liquid crystal material is filled in a space between the lower substrate 400 and the upper substrate 600, substantially constituting the liquid crystal layer 450. Consequently, a liquid crystal display 490 is formed as shown in FIG. 4.

It is noted that the color filter units described in the above embodiments are illustrated as two-dimensional color filter arrays including a periodic pattern of red (R), green (G) and blue (B) filters and are not limited thereto. However, the color filter units described in the above embodiments may additionally be a two-dimensional color filter array including a periodic pattern of different colors of cyan (Cy), magenta (Mg), and yellow (Ye) filters. The red pattern can be substituted by the cyan pattern, the green pattern can be substituted by the yellow pattern and the blue pattern can be substituted by the magenta pattern. In the above embodiments, the final forming of the color layer on the color filter is patterned by an etching back or a CMP process which yields color filters having a greater flatness than the color filters made by conventional techniques. The advantages of above embodiments include: 1) at least one photolithography process may be omitted during the whole process; and 2) the cross-talk problem caused by misalignment can be improved. Moreover, since a color filter with a high degree of flatness can be obtained if the final color layer is patterned by CMP process, the planarization layer disposed on the color filter in conventional color image sensors may be omitted.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a color image sensor device, comprising:
providing a substrate comprising a sensor pixel array;
forming an intermetal dielectric layer on the substrate, covering the sensor pixel array;
blanketly forming a first planarization layer on the intermetal dielectric layer;
forming a first color layer over the first planarization layer;
exposing and developing the first color layer to form a patterned first color filter unit over the sensor pixel array;
forming a second color layer over the first planarization layer and the patterned first color filter unit;
exposing and developing the second color layer to form a patterned second color filter unit next to the patterned first color filter unit over the sensor pixel array;
forming a third color layer over the first planarization layer and the patterned first and second color filter units; and
etching back or chemical mechanical polishing (CMP) to form a patterned third color filter unit between the patterned first and second color filter units over the sensor pixel array.

2. The method for fabricating a color image sensor device as claimed in claim 1, further comprising:
forming a second planarization layer on the first planarization layer, covering the patterned first, second and third color filter unit; and
forming a microlenses array over the second planarization layer corresponding to the sensor pixel array.

3. The method for fabricating a color image sensor device as claimed in claim 1, further comprising forming a passivation layer on the intermetal dielectric layer.

4. The method for fabricating a color image sensor device as claimed in claim 1, wherein the intermetal dielectric layer is a composite layer, comprising two or more intermetal dielectric layers.

5. The method for fabricating a color image sensor device as claimed in claim 1, wherein the first color layer, the second color layer and the third color layer are of different colors selected from a group consisting of green, blue and red.

6. The method for fabricating a color image sensor device as claimed in claim 1, wherein the first color layer, the second color layer and the third color layer are of different colors selected from a group consisting of cyan, magenta and yellow.

7. The method for fabricating a color image sensor device as claimed in claim 1, wherein the first planarization layer and the second planarization layer are made of transparent resin or photoresist.

8. A method for fabricating a color filter, comprising:
providing a substrate having a display area;
forming a light shielding layer on the substrate, and separating the display area into a plurality of sub-pixels;
forming a first color layer over the substrate and in the plurality of sub-pixels;
exposing and developing the first color layer to form a patterned first color filter unit in the plurality of sub-pixels;
forming a second color layer over the substrate and the patterned first color filter unit and in the plurality of sub-pixels;
exposing and developing the second color layer to form a patterned second color filter unit in the plurality of sub-pixels;
forming a third color layer over the substrate and the patterned first and second color filter units and in the plurality of sub-pixels;
etching back or chemical mechanical polishing (CMP) the third color layer to form a patterned third color filter unit in the plurality of sub-pixels; and
forming a conductive layer over the light shielding layer.

9. The method for fabricating a color filter as claimed in claim 8, wherein the first color layer, the second color layer and the third color layer are of different colors selected from a group consisting of green, blue and red.

10. The method for fabricating a color filter as claimed in claim 8, wherein the first color layer, the second color layer and the third color layer are of different colors selected from a group consisting of cyan, magenta and yellow.

11. The method for fabricating a color filter as claimed in claim 8, wherein the conductive layer is comprised of layer is comprised of ITO, IZO, ZnO:Sn, ZnO:V, ZnO:Co, ZnO:Al, ZnO:Ga, ZnO:Ti or ZnO:In.

12. The method for fabricating a color filter as claimed in claim 8, wherein the conductive layer is formed by sputtering, evaporation or electroless plating.

13. The method for fabricating a color filter as claimed in claim 8, wherein the light shielding layer is made of black resin or black acrylic.

14. A method for fabricating a color filter, comprising:
providing a substrate;
forming a planarization layer on the substrate;
forming a first color layer over the planarization layer;
exposing and developing the first color layer to form a patterned first color filter unit over the planarization layer;
forming a second color layer over the planarization layer and the patterned first color filter unit;
exposing and developing the second color layer to form a patterned second color filter unit over the planarization layer;
forming a third color layer over the planarization layer and the patterned first and second color filter units; and
etching back or chemical mechanical polishing (CMP) the third color layer to form a patterned third color filter unit over the planarization layer.

15. The method for fabricating a color filter as claimed in claim 14, wherein the first color layer, the second color layer and the third color layer are of different colors selected from a group consisting of green, blue and red.

16. The method for fabricating a color filter as claimed in claim 14, wherein the first color layer, the second color layer and the third color layer are of different colors selected from a group consisting of cyan, magenta and yellow.

17. The method for fabricating a color filter as claimed in claim 14, wherein the planarization layer is made of transparent resin or photoresist.
